(19) United States
(12) Patent Application Publication
(10) Pub. No.: US 2010/0209605 A1
(43) Pub. Date: Aug. 19, 2010

(54) Anchored Nanostructure Materials and Ball Milling Method Of Fabrication

(75) Inventors: Paul A. Menchhofer, Clinton, TN (US); Roland D. Seals, Oak Ridge, TN (US); Cristian I. Contescu, Knoxville, TN (US); Timothy D. Burchell, Oak Ridge, TN (US)

Correspondence Address: BWXT - Y12, LLC;LUEDEKA, NEELY & GRAHAM, P.C., P.O. BOX 1871, KNOXVILLE, TN, 37901, US

(73) Assignee: BABCOCK & WILCOX TECHNICAL SERVICES Y-12, LLC, Oak Ridge, TN (US)

(21) Appl. No.: 12/704,573

(22) Filed: Feb. 12, 2010

Related U.S. Application Data
(60) Provisional application No. 61/152,380, filed on Feb. 13, 2009.

(51) Int. Cl. C23C 16/26; C23C 16/02

(52) U.S. Cl. 427/216; 977/840

(57) ABSTRACT

Anchored nanostructure materials and methods for their fabrication are described. The anchored nanostructure materials may utilize nano-catalysts that are formed by mechanical ball milling of a metal powder. Nanostructures may be formed as anchored to the nano-catalyst by heating the nanocatalysts and then exposing the nano-catalysts to an organic vapor. The nanostructures are typically single wall or multi-wall carbon nanotubes.

### CROSS REFERENCES TO RELATED APPLICATIONS

This patent application claims priority from and is related to U.S. Provisional Patent Application No. 61/152,380 filed 13 Feb. 2009, entitled “Anchored Nanostructure Materials and Ball Milling Method of Fabrication.” Provisional Patent Application No. 61/152,380 is incorporated by reference in its entirety herein.

### GOVERNMENT RIGHTS

The U.S. Government has rights to this invention pursuant to contract number DE-AC05-00OR22800 between the U.S. Department of Energy and Babcock & Wilcox Technical Services, LLC.

This invention was made with government support under Contract No. DE-AC05-00OR22725 awarded by the U.S. Department of Energy. The government has certain rights in the invention.

### FIELD

This disclosure relates to the field of nanomaterials. More particularly, this disclosure relates to nanomaterials anchored to powder particles.

### BACKGROUND

Nanostructures are objects that have physical dimensions between those of sub-atomic-scale (less than one Angstrom-sized) structures and microscopic-scale (greater than one tenth micrometer-sized) structures. Nanostructures are said to have nano-scale features. “Nano-scale” refers to a dimension that is between approximately one Angstrom (0.1 nanometer) and approximately 100 nanometers (0.1 micrometer). Nano-scale features may occur in one, two, or three dimensions. For example, nano-textured surfaces have one nano-scale dimension. That is, such surfaces have nano-features such as ridges, valleys or plateaus that provide surface height variations that range from about 0.1 to about 100 nanometers. Another example of a one-dimension nanostructure is a film that has a thickness that ranges from about 0.1 to about 100 nanometers. Nanotubes are examples of nanostructures that have two nano-scale dimensions. That is, a nanotube has a diametral dimension and a length. The diametral dimension of a nanotube ranges from about 0.1 to about 100 nanometers. The length of a nanotube may be greater than hundreds of microns. Nanoparticles have three diametral nano-scale dimensions. Each diametral dimension of a nanoparticle ranges from about 0.1 to about 100 nm.

Nanostructures may be formed from carbon, silicon, boron, various metal and metalloid elements, various compounds, alloys and oxides of those elements, ceramics, various organic materials including monomers and polymers, and potentially any other material. Nanostructures have potential use in various physical, chemical, mechanical, electronic and biological applications. Nanomaterials are collections of nanostructures. The formation, collection, and assembly of nanomaterials generally involve difficult and expensive processes. One major issue with nanomaterials is the difficulty of production of the nanostructures in sufficient quantity, purity, and uniformity of morphology to be useful. What are needed therefore are better systems and methods for manufacturing nanomaterials.

### SUMMARY

In one embodiment the present disclosure provides a method of producing an anchored nanostructure material for fabricating composite materials, the steps of which may be performed in any order. One step of this method typically includes ball milling a metal powder to form nanocatalyst material. A further step includes heating the nano-catalyst material under a protective atmosphere to a temperature ranging from about 450° C. to about 1500° C. A final step of the method is typically exposing the heated nano-catalyst to an organic vapor to affix carbon nanostructures to the nano-catalyst and form the anchored nanostructure material. In some embodiments the step of exposing the heated nano-catalyst to an organic vapor includes flowing the organic vapor proximal to the heated nano-catalyst at a rate ranging from about 100 cc/min to about 10 L/min. In some embodiments the step of exposing the heated nano-catalyst to an organic vapor includes exposing the heated nano-catalyst to the organic vapor at a process pressure in a range from about 1 torr to about 1000 torr. Some embodiments include further steps of cooling the anchored nanostructure material under a protective atmosphere to a temperature at which the anchored nanostructure material does not significantly oxidize in an ambient atmosphere, and then discontinuing the protective atmosphere and providing access to the anchored nanostructure material in the ambient atmosphere.

### BRIEF DESCRIPTION OF THE DRAWINGS

Various advantages are apparent by reference to the detailed description in conjunction with the figures, wherein elements are not to scale so as to more clearly show the details, wherein like reference numbers indicate like elements throughout the several views, and wherein:

FIGS. 1A and 1B are photomicrographs of anchored nanostructure material.

FIG. 2A is a schematic diagram of a fabrication system for producing anchored nanostructure materials.

FIG. 2B is a schematic diagram of a simplified fabrication system for producing anchored nanostructure materials.

### DETAILED DESCRIPTION

In the following detailed description of the preferred embodiments, reference is made to the accompanying drawings, which form a part hereof, and within which are shown by way of illustration the practice of specific embodiments of methods of fabricating nano-catalysts. It is to be understood that other embodiments may be utilized, and that structural changes may be made and processes may vary in other embodiments.

Disclosed herein are various processes for fabricating nano-catalysts that have utility for forming nanostructures and manufacturing nanomaterials, and methods of using such nano-catalysts for fabricating anchored nanostructure materials.

Powder-based nano-catalysts may be used in various processes to produce nanostructures and nanomaterials. For example, powder-based nano-catalysts may be used to grow carbon nanotubes that may be harvested and used as nanomaterials. The powder-based nano-catalysts may also be incorporated as a constituent of components and coatings that then have catalytic properties for enhancing the formation of nanostructures within the component or the coating. That is, instead of first fabricating and collecting nanostructures as nanomaterials and then mixing those nanomaterials with other constituents to form nanostructure-bearing composite materials, powder-based nano-catalysts may be mixed with other constituents and nanostructures may then be grown in-situ to form nanostructure-bearing composite materials. The nanostructure-bearing composite material may be formed as a layer that is disposed adjacent the surface of a component or the nanostructure-bearing composite material may be formed as a portion or all of the bulk material of the component.

Mechanical and thermal processes may be used to form nanostructure features adjacent the surface of powder materials of interest. Putting mechanical work into the material surface generates nanostructure features on the surface of the material. Mechanical ball milling is an example of such a mechanical process. Grinding and forging-like processes may also be used to mechanically form nanostructure features adjacent the surface of powder materials. Heat cycling and thermal spraying are examples of thermal processes.

Ball milling is typically accomplished by placing solid spheres (balls) made of a suitably hard ceramic material in a cylindrical tumbler along with the material to be milled. The axis of the cylindrical tumbler is horizontal and the tumbler and its contents are rotated about the axis over an extended period of time (typically several hours) to pulverize the material to be milled.

In one embodiment Ni and Al powders are ball milled together until nano-scale features form adjacent the surface of the powder particles. In some embodiments various combinations of the following metals may be ball milled together, either as individually, jointly or in combination with Ni and Al: (1) Co and Al, (2) Fe and Al, and 3) cobalt containing and iron containing powders (such as steel). The resultant structures are an example of a powder-based nanocatalyst.

Powder-based nano-catalysts may be used to grow nanostructures, and in particular to grow carbon nanotubes. Nanostructures that are grown are attached to the nano-scale features formed adjacent the surface of the powder particles. These nanostructures may be grown at temperatures starting as low as 450° C., although around 600° C. is better and preferably the nanostructures are grown at higher temperatures, typically ranging from about 600° C. to about 1200° C. In a typical embodiment, single-wall or multi-wall carbon nanotubes may be grown on a powder-based nano-catalyst. The powder-based nano-catalyst is placed in a process vessel and loaded into a furnace. A quartz tube is typically used as the process vessel because quartz is chemically inert and tolerant of high temperatures, and various sizes of quartz tubes are readily available. High temperature corrosion-resistant metals (such as Inconel) or ceramics may also be used to fabricate suitable process vessels. A vacuum is drawn and the nano-catalyst is heated to a target temperature ranging from about 500° C. to about 1500° C., with 600° C. being typical. The specific target temperature is designed to approach but not exceed the lower of the melting temperature of the powder or the nanoparticles formed on the powder. Various sources of heating may be used. Infrared heating using a quartz tube is beneficial because quartz is substantially transparent to infrared radiation, so that almost all of the heating energy passes through the process vessel and is absorbed by the reacting materials. Microwave heating may also be used, preferably with a microwave-transparent process vessel.

In alternate embodiments an inert gas may be used instead of the drawing a vacuum in the furnace. The term “protective atmosphere” is used herein to refer to either a vacuum or an inert gas. The target temperature is maintained typically for about two hours, but may range from about five minutes to about twenty-four hours, while an organic vapor, such as ethanol vapor, is flowed through the furnace at a rate ranging from about 100 cc/minute to about 10 L/minute (depending on the volume of the chamber), typically about 100 cc/minute to about 150 cc/minute. Typically this establishes an organic vapor process pressure ranging from about 1 torr to about 1000 torr, typically about 400 torr, within the tube furnace for about a ten minute duration. During this process nanostructures, specifically carbon nanotubes, attach to and grow on the nanoparticles adjacent the surface of the powder particles. The resultant nano-catalyst/nanostructure constructs are referred to herein as anchored nanostructure materials. The rate of growth and physical attributes of these anchored nanostructure materials may be varied by adjusting the organic vapor pressure, the flow rate, the temperature, the time of exposure, and the concentration of nanoparticles adjacent the surface of the powder particles. After a desired amount of growth is complete, the organic vapor exposure is discontinued, the anchored nanostructure material is removed from the furnace hot zone to a near-room temperature zone (within the quartz tube) while maintaining vacuum. The quartz tube and its contents are allowed to cool, and then the anchored nanostructure materials may be removed from the quartz tube.

In some embodiments where such nano-catalysts are used to produce carbon nanotubes the hydrogen gas flow is applied both (a) during the reduction of the precipitated metal ions (nano-size spots or nano-size dots) to metal nano-catalysts and also (b) during a subsequent ethanol (or other organic) gas flow over the nano-catalysts to form carbon nanotubes. Having hydrogen present during the formation of carbon nanotubes prevents the catalysts from becoming “dead.” The metal nanoparticles remain active as catalysts for extended periods of time which allows the high volume of carbon nanotubes to be grown. This process makes the catalysts very efficient. The same technique of flowing hydrogen gas during the formation, growth and production of carbon nanotubes may be applied to processes using other nano-catalysts that were generated by mechanical, thermal, or chemical means to prolong the “active life” of the catalysts and thus prolong the growth/production of carbon nanotubes.

These nanostructure materials are sometimes referred to as being formed “in-situ” because the formation of the nanostructures (e.g., carbon nanotubes) on the individual powder particles occurs on powder particles which may subsequently be used to fabricate composite materials that incorporate the anchored nanostructure material, without transferring the nanostructures to another material or powder for final use.

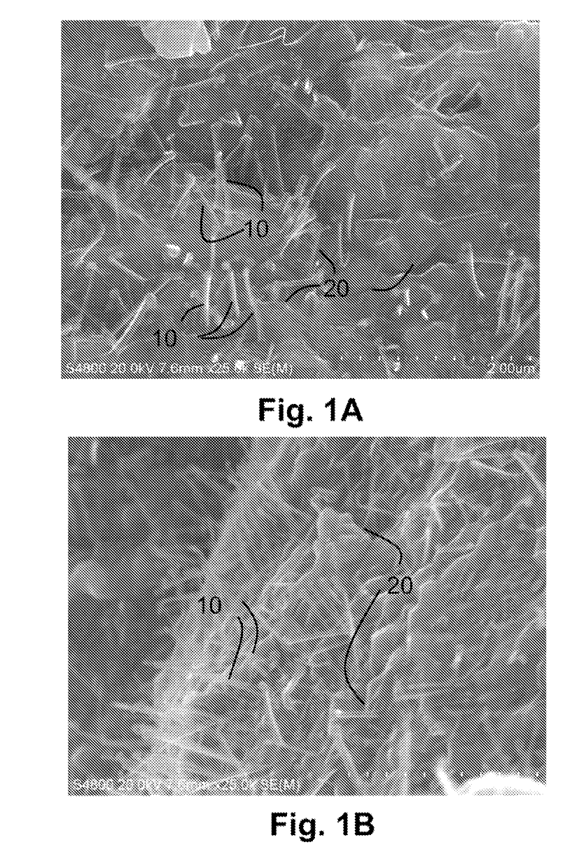

FIGS. 1A and 1B are photomicrographs of anchored nanostructure material 10 grown on ball milled Ni and Al powders 20. The nanostructures are carbon nanotubes that range in diameter from about 60 to about 80 nm in diameter.

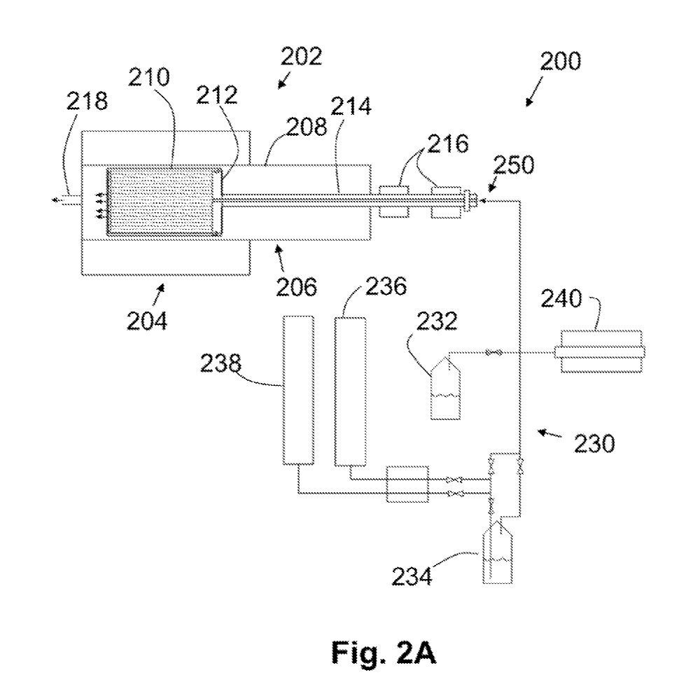

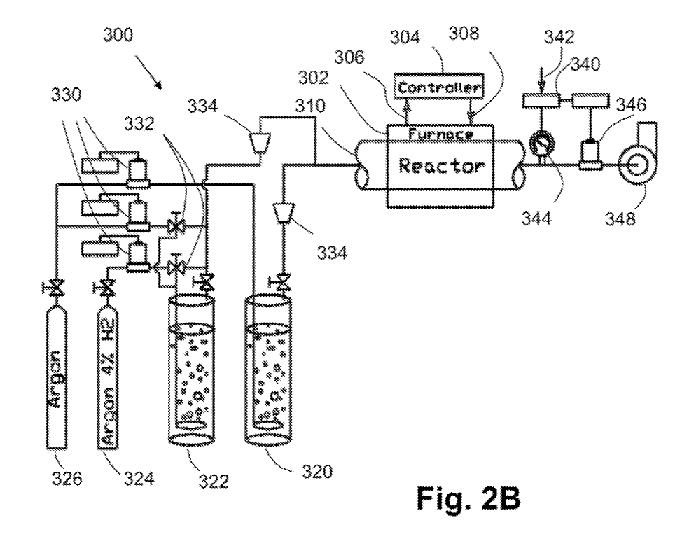

FIG. 2A presents a schematic diagram of a fabrication system 200 for producing anchored nanostructure materials. Fabrication system 200 includes a furnace 202 that has a hot zone 204 and a transfer zone 206. The furnace 202 includes a cylindrical quartz tube 208 that is configured to house a cylindrical process vessel 210 that also may be fabricated from quartz. The cylindrical process vessel 210 may include a peg-lock end cap 212, or a similar structure, to facilitate the loading of nano-catalysts into the cylindrical process vessel 210, and the removal of anchored nanostructure materials from the cylindrical process vessel 210 after processing. Although not essential, a cylindrical hollow quartz shaft 214 is provided to move the cylindrical process vessel 210 between the transfer zone 206 and the hot zone 204 of the furnace 202. The cylindrical hollow quartz shaft 214 passes through a pair of bearings 216 that permit axial and rotational movement of the cylindrical hollow quartz shaft 214 and the cylindrical process vessel 210. An evacuation port 218 is provided in the furnace 202, and the evacuation port 218 may be used to provide a vacuum in the cylindrical process vessel 210. The evacuation port 218 may also be use to extract process gases from the cylindrical process vessel 210, so that a flow of process gases is maintained through the cylindrical process vessel 210.

Fabrication system 200 also includes a process gas system 230. The process gas system typically includes a source of ethanol 232. A source of water vapor 234 may also be provided. Typically for processes used to fabricate anchored carbon nanotubes, the water vapor 234 is supplied at a rate of about 50 to 500 parts per million by decomposition of ethanol that is used to grow the carbon nanotubes. The water vapor oxidizes away any carbon that is not a nanostructure. In some embodiments a mixture 236 of methane and air (in approximately a 50:50 ratio) may be provided as well as a source of auxiliary gas 238. Methane may be used as an alternative or supplement to ethanol as a source of carbon for growing carbon nanotubes. A gas stream monitoring system 240 may be provided to monitor levels of oxygen, water vapor, hydrogen, carbon monoxide, methane, etc. The gas from process gas system 230 is provided to the cylindrical hollow quartz shaft 214 at a coupling 250.

In an exemplary embodiment, a powder-based nano-catalyst (e.g., ball milled Ni and Al powders 20 of FIG. 1A or 1B) is disposed within a “boat” such as cylindrical process vessel 210 of FIG. 2A. The cylindrical process vessel 210 is positioned in a “cold zone” (such as transfer zone 206 of FIG. 2A) and then moved into the “hot zone” (e.g., 204 of FIG. 2A) of a furnace (e.g., 202 of FIG. 2A) via a feed-thru device (e.g., quartz tube 208 of FIG. 2A) under a protective atmosphere. A flowing mixture of ethanol (e.g., from source 232 of FIG. 2A) and hydrogen and argon (e.g., from auxiliary source 238 of FIG. 2A) at between 500° C. to 1500° C. (about 600° C. is typical) at ˜100 cc/minute to establish a pressure of approximately 400 torr within the tube furnace for a duration of about 15 minutes (although time durations may be less or may extend up to about 24 hours). This grows carbon nanotubes on the powder-based nanocatalysts. Flowing hydrogen gas during the formation, growth and production of carbon nanotubes prolongs the “active life” of the catalysts and thus prolongs the growth/production of carbon nanotubes. Water vapor (e.g., from source 234 of FIG. 2A) may be added to oxidize carbon that is not formed as nanotubes. The powdered nano-catalysts with anchored carbon nanotubes are moved back to the cold zone (e.g., transfer zone 206 of FIG. 2A) and cooled while maintaining the protective atmosphere. After cooling, the powder-based nano-catalysts with anchored carbon nanotubes may be removed from the process vessel (e.g., 210 of FIG. 2A).

FIG. 2B illustrates a further embodiment of an apparatus 300 for manufacturing anchored nanostructure materials. The apparatus includes a furnace 302 that is operated by a controller 304. A thermocouple 306 provides temperature information to the controller 304 and the controller 304 drives a power line 308 to control the temperature of the furnace 302. The furnace 302 is configured for heating a reactor vessel 310. Various gas delivery systems are provided. One gas delivery system is an ethanol tank 320 and a water tank 322. The ethanol tank 320 and the water tank 322 are typically wrapped with heat tape to raise the temperature of their contents to a temperature ranging from room temperature to the boiling point. Porous frits may be disposed in the tanks to enhance thermal stability and to disperse the gas, increasing contact area with the content, thus, allowing the gas to act as a carrier or “pickup” of the liquid. Further gas delivery systems include argon/hydrogen tanks 324 and an argon purge gas tank 326 for controlling the atmosphere in the furnace 302. Flow controllers 330 are provided in conjunction with a system of valves 332 (typical) and rotameters 334 to control gas flow. A pressure controller 340 with a set point adjustment 342, a pressure gauge 334, and a mass flow controller 346 are used to control the pressure in the reactor through a vacuum pump 348.

The apparatus 300 of FIG. 2B is operated in the manner described for the operation of the fabrication system 200 of FIG. 2A, with a furnace 302 temperature ranging from about 450° C. to about 1200° C. (typically 600° C.) and gas flow rates ranging between 100 and 1000 cc/min (typically 125-150 cc/min). Water vapor concentration is provided in a range from about 50 to 500 ppm.

In summary, embodiments disclosed herein provide various methods for fabricating anchored nanostructure materials, including ball milling processes. The anchored nanostructure materials may utilize nano-catalysts that are powder-based or solid-based. The substrate powders or solids may comprise metal, ceramic, or silicon or other metalloid. The nanostructures that are anchored to the nano-catalysts are typically single wall or multi-wall carbon nanotubes.

The foregoing descriptions of embodiments have been presented for purposes of illustration and exposition. They are not intended to be exhaustive or to limit the embodiments to the precise forms disclosed. Obvious modifications or variations are possible in light of the above teachings. The embodiments are chosen and described in an effort to provide the best illustrations of principles and practical applications, and to thereby enable one of ordinary skill in the art to utilize the various embodiments as described and with various modifications as are suited to the particular use contemplated. All such modifications and variations are within the scope of the appended claims when interpreted in accordance with the breadth to which they are fairly, legally, and equitably entitled.

What is claimed is:

1. A method of producing an anchored nanostructure material for fabricating composite materials, comprising:
(a) ball milling a metal powder to form nanocatalyst material;
(b) heating the nano-catalyst material under a protective atmosphere to a temperature ranging from about 450° C. to about 1500° C.; and
(c) exposing the heated nano-catalyst to an organic vapor to affix carbon nanostructures to the nano-catalyst and form the anchored nanostructure material.

2. The method of claim 1 wherein step (c) comprises flowing the organic vapor proximal to the heated nano-catalyst at a rate ranging from about 100 cc/min to about 10 L/min.

3. The method of claim 1 wherein step (c) comprises exposing the heated nano-catalyst to the organic vapor at a process pressure in a range from about 1 torr to about 1000 torr.

4. The method of claim 1 further comprising:
(d) cooling the anchored nanostructure material under a protective atmosphere to a temperature at which the anchored nanostructure material does not significantly oxidize in an ambient atmosphere; and
(e) discontinuing the protective atmosphere and providing access to the anchored nanostructure material in the ambient atmosphere.
